(19) United States
(12) Patent Application Publication
(10) Pub. No.: US 2025/0368892 A1
(43) Pub. Date: Dec. 4, 2025

(54) METHOD OF FABRICATING QUANTUM-DOT STRUCTURE THROUGH SELF-ASSEMBLY AND QUANTUM-DOT STRUCTURE

(71) Applicant: POSTECH RESEARCH AND BUSINESS DEVELOPMENT FOUNDATION, Pohang-si (KR)

(72) Inventors: Byoung-don KONG, Pohang-si (KR); Cheulhyun YOON, Pohang-si (KR); Jeongwook KIM, Pohang-si (KR); Seokhyun YOON, Pohang-si (KR); Gyeong Min SEO, Pohang-si (KR); Suhyun PARK, Pohang-si (KR)

(21) Appl. No.: 19/300,859

(22) Filed: Aug. 15, 2025

Related U.S. Application Data
(63) Continuation-in-part of application No. PCT/KR2024/008622, filed on Jun. 21, 2024.

(30) Foreign Application Priority Data
Jun. 23, 2023 (KR) 10-2023-0081148

(51) Int. Cl. C09K 11/66; B82Y 20/00; B82Y 40/00; C09K 11/02; H10D 30/01; H10D 30/40; H10D 62/10

(52) U.S. Cl. CPC C09K 11/66; C09K 11/025; H10D 30/014; H10D 30/402; H10D 62/119; B82Y 20/00; B82Y 40/00

(57) ABSTRACT

A method of fabricating a quantum-dot structure includes the steps of preparing a semiconductor material layer formed on a substrate; forming an insulating layer from a portion of the semiconductor material layer by oxidizing the semiconductor material layer; and forming quantum dots which are located in the insulating layer and are made of a semiconductor material by diffusing the semiconductor material into the insulating layer by annealing. According to the method of fabricating the quantum-dot structure, it is possible to form the quantum dots made of the semiconductor material from the substrate through self-assembly. According to the method of fabricating the quantum-dot structure, it is possible to form quantum dots and a tunneling structure thereof through self-assembly, and it is possible to fabricate devices such as a single electron transistor based on quantum dots, using processes of existing silicon (Si)-based devices.

### CROSS-REFERENCE TO RELATED APPLICATIONS

This application is a Continuation-in-Part of International Patent Application No. PCT/KR2024/008622, filed on Jun. 21, 2024, which claims the benefit of priority to Korean Patent Application No. 10-2023-0081148, filed on Jun. 23, 2023, the entire contents of which are incorporated herein by reference.

### BACKGROUND

### Field

The present disclosure relates to a method of fabricating a quantum-dot structure and a quantum-dot structure. More particularly, the present disclosure relates to a technology that fabricates a tunneling structure including quantum dots and an insulating film through self-assembly using a nanopillar structure which can adjust the size and positions of the quantum dots.

### Description of the Related Art

Since semiconductor quantum dots have electronic characteristics different from those of existing bulk structures, the semiconductor quantum dots are actively used in various fields such as a display field, a laser field, a solar cell field, and a medical field.

A quantum confinement effect which is a phenomenon emerging as excitons are confined in all directions because a size of semiconductor quantum dots is smaller than an intrinsic exciton Bohr radius of a material is an important characteristic of quantum dots. Accordingly, the semiconductor quantum dots have the same energy band as single atoms, and can implement desired electrical and/or optical characteristics through appropriate bandgap control. In addition, a single electron tunneling phenomenon using the quantum confinement effect enables a current flow at a nanometer level, thereby realizing nano devices having low power and high integration, using the single electron tunneling phenomenon.

However, a quantum dot-based nano device should operate at room temperature so as to mass-produce the device, and to this end, silicon-based quantum dots should be formed with a size of a few nanometers.

A quantum dot forming method according to a conventional art may be divided into a top-down method and a bottom-up method. The top-down method is a method of forming a high-dimensional bulk material into a zero-dimensional bulk material, but there is a problem that the minimum size of devices to be formed according to the minimum line width of lithography is limited. In order to solve this problem, quantum dots with a size of a few nanometers have recently been formed by a forming method using the bottom-up method, such as synthesizing chemical quantum dots from a colloidal material through a chemical process. However, in the case of this method, a problem that it is difficult to process quantum dots randomly distributed in a solution into an available device has not yet been resolved.

In the case of complementary metal-oxide semiconductor (CMOS) semiconductors, the size of the devices is coming close to a few nanometer levels, and therefore, fundamental changes in transistor structure and fabrication method are required. However, in the quantum dot forming method according to the conventional art, it is difficult to form quantum dots into a device having an accurate form by uniformly adjusting the positions and size of the quantum dots, and hence there is a limitation that it is hard to apply the quantum dot forming method to existing integrated circuit technologies to form quantum dots with a size of a few nanometers.

### SUMMARY

The present disclosure is directed to providing a method of fabricating a quantum-dot structure and a quantum-dot structure, which, unlike the quantum dot forming method according to the conventional art, can accurately adjust the positions and size of quantum dots through self-assembly capable of controlling design and processes of the quantum dots and can be easily grafted onto existing silicon (Si)-based processes to enable realization of ultra-low power and ultra-large scale integration nano devices.

According to an aspect of the present disclosure, a method of fabricating a quantum-dot structure comprises: preparing a semiconductor material layer formed on a substrate; forming an insulating layer from a portion of the semiconductor material layer by oxidizing the semiconductor material layer; and forming quantum dots which are located in the insulating layer and are made of a semiconductor material by diffusing the semiconductor material into the insulating layer by annealing.

In an embodiment, preparing the semiconductor material layer comprises epitaxially growing the semiconductor material layer from the substrate.

In an embodiment, the substrate comprises silicon (Si), and the semiconductor material layer comprises silicon germanium (SiGe).

In an embodiment, forming the insulating layer comprises oxidizing a portion of the semiconductor material layer by heating the semiconductor material layer while injecting oxygen.

In an embodiment, forming the insulating layer further comprises forming a mixture layer comprising a semiconductor material and oxygen between the semiconductor material layer and the insulating layer.

In an embodiment, forming the insulating layer comprises heating the semiconductor material layer at a temperature of exceeding 0° C. and less than 600° C. under an atmosphere comprising oxygen.

In an embodiment, forming the quantum dots comprises inducing diffusion of a semiconductor material into the insulating layer from the semiconductor material layer and the mixture layer by annealing.

In an embodiment, the mixture layer comprises silicon germanium oxide, and the quantum dots are made of germanium (Ge).

In an embodiment, forming the quantum dots comprises heating the semiconductor material layer and the insulating layer at a temperature of 600° C. or higher to induce diffusion of a semiconductor material.

In an embodiment, forming the quantum dots comprises adjusting at least one of a heating time and a heating temperature of the semiconductor material layer and the insulating layer to adjust a size of the quantum dots.

In an embodiment, the method of fabricating a quantum-dot structure further comprises forming a protective layer for interrupting a reaction on the insulating layer after forming the insulating layer and before forming the quantum dots.

In an embodiment, the protective layer comprises titanium nitride (TiN).

In an embodiment, the method of fabricating a quantum-dot structure further comprises: etching the insulating layer in a shape of nanopillars before forming the quantum dots, forming a first conductive layer on the insulating layer; and forming a second conductive layer surrounding the insulating layer in the shape of the nanopillars on the semiconductor material layer.

According to an aspect of the present disclosure, a quantum-dot structure comprises: a semiconductor material layer; an insulating layer located on the semiconductor material layer; and quantum dots formed from a semiconductor material diffused into the insulating layer to be located in the insulating layer, wherein the quantum dots are electrically isolated from the semiconductor material layer by a tunneling barrier formed by the insulating layer.

In an embodiment, the semiconductor material layer comprises silicon germanium (SiGe), the insulating layer comprises silicon dioxide (SiO₂), and the quantum dots are made of germanium (Ge).

In an embodiment, the quantum-dot structure further comprises: a mixture layer located between the insulating layer and the semiconductor material layer, the mixture layer including a semiconductor material and oxygen.

In an embodiment, the insulating layer including the quantum dots has the shape of nanopillars.

In an embodiment, the quantum-dot structure further comprises: a first conductive layer located on the insulating layer; and a second conductive layer located on the semiconductor material layer, the second conductive layer surrounding the insulating layer.

In an embodiment, the quantum dots are electrically isolated from the first conductive layer and the second conductive layer by a tunneling barrier formed by the insulating layer.

According to an aspect of the present disclosure, a single electron transistor comprises the quantum-dot structure according to embodiments disclosed above.

According to an aspect of the present disclosure, a quantum-dot structure is fabricated by the steps of: preparing a semiconductor material layer formed on a substrate; forming an insulating layer from a portion of the semiconductor material layer by oxidizing the semiconductor material layer; and forming quantum dots which are located in the insulating layer and are made of a semiconductor material by diffusing the semiconductor material into the insulating layer by annealing.

According to a method for fabricating a quantum-dot structure according to an embodiment of the present disclosure, a quantum-dot structure may be formed, which includes quantum dots made of a semiconductor such as germanium and an insulating layer capable of adjusting the probability of electrons that tunnel at an energy level of the quantum dots.

According to the method of fabricating the quantum dot structure, it is possible to fabricate the quantum-dot structure through self-assembly in which reproducibility and mass production are possible. In addition, the method of fabricating the quantum dot structure can be easily grafted onto existing silicon (Si)-based processes.

According to a method for fabricating a quantum-dot structure according to an embodiment of the present disclosure, it is possible to adjust positions and a size of quantum dots through a heating process of a silicon semiconductor compound, and it is possible to form quantum dots with a nanometer size, so that when the quantum-dot structure is applied to a nano device, a stable operation of the device is possible at room temperature. Furthermore, a flow of current of a nano structure semiconductor is controlled, so that it is possible to realize ultra-low power semiconductor devices.

A quantum-dot structure fabricated based on quantum dots according to an embodiment of the present disclosure have the form of a resonant tunneling diode including a source electrode, quantum dots, and a drain electrode, and it is possible to realize a single electron transistor through a process of forming a gate electrode from the quantum-dot structure. The quantum-dot structure fabricated as described above has advantages in that modeling for analyzing electrical performance of quantum dots is relatively simple and the quantum-dot structure is suitable for realization of ultra-low power and ultra-large scale integration devices.

### BRIEF DESCRIPTION OF THE DRAWINGS

FIG. 1 is a flowchart illustrating steps of a method of fabricating a quantum-dot structure according to an embodiment.

FIG. 2 is a perspective view of a sample for the method of fabricating the quantum-dot structure according to the embodiment.

FIG. 3 is a sectional view taken along line A-A′ of the sample shown in FIG. 2.

FIG. 4 is a sectional view of the sample which has undergone a low temperature oxidation process in the method of fabricating the quantum-dot structure according to the embodiment.

FIG. 5 is a sectional view of the sample which has undergone a protective layer deposition process in the method of fabricating the quantum-dot structure according to the embodiment.

FIG. 6 is a sectional view of the sample in which quantum dots are formed through self-assembly by the method of fabricating the quantum-dot structure according to the embodiment.

FIGS. 7A through 7C are conceptual views illustrating a process of forming quantum dots through self-assembly by the method of fabricating the quantum-dot structure according to the embodiment.

FIG. 8 is a scanning transmission electron microscopy image showing a result obtained by forming quantum dots by the method of fabricating the quantum-dot structure according to the embodiment.

FIG. 9 is a flowchart illustrating steps of a method of fabricating a quantum-dot structure according to another embodiment.

FIG. 10A is a sectional view showing a sample etched by the method of fabricating the quantum-dot structure according to the another embodiment.

FIG. 10B is a sectional view showing that quantum dots are formed through a high temperature annealing process on the sample of FIG. 10A.

FIG. 11 is a perspective view showing the sample in which a conductive layer is formed by the method of fabricating the quantum-dot structure according to the another embodiment.

FIG. 12 is a section view of a transistor formed by the method of fabricating the quantum-dot structure according to the another embodiment.

FIG. 13 is a sectional view taken along line B-B′ of the transistor shown in FIG. 12.

FIG. 14A is an image showing a result obtained by measuring a section after oxidation of a silicon germanium (SiGe) layer at a temperature of 600° C., using a scanning transmission electron microscopy (STEM).

FIG. 14B is a graph showing a secondary ion mass spectrometry (SIMS) result of silicon germanium oxide shown in FIG. 14A.

FIG. 15 is an image showing an EDS element mapping result of the silicon germanium oxide shown in FIG. 14A.

FIG. 16A shows a result obtained by measuring a section after oxidation of the silicon germanium (SiGe) layer at a temperature of about 850° C., using the STEM.

FIG. 16B is a graph showing a SIMS result of the silicon germanium oxide shown in FIG. 16A.

FIG. 17 is an image showing an EDS element mapping result of the silicon germanium oxide shown in FIG. 16A.

FIGS. 18A and 18B are images showing a result obtained by forming germanium (Ge) quantum dots in an insulating layer.

FIG. 19 is an image showing an EDS element mapping result of a quantum-dot structure shown in FIGS. 18A and 18B.

FIG. 20A is an image showing a result obtained by measuring a section of the quantum-dot structure in which the germanium quantum dots exist in the insulating layer, using the STEM.

FIG. 20B is a graph showing a capacitance-voltage (C-V) measurement result of the quantum-dot structure shown in FIG. 20A.

### DETAILED DESCRIPTION

Hereinafter, embodiments of the present disclosure will be described in detail with reference to the accompanying drawings.

In describing an embodiment of the present disclosure, when a certain description of well-known elements or functions is deemed to make the subject matter of an embodiment of the present disclosure ambiguous, its detailed description is omitted herein. Additionally, in the drawings, elements irrelevant to the description of an embodiment of the present disclosure are omitted, and like reference signs are affixed to like elements.

In an embodiment of the present disclosure, when an element is referred to as being “connected”, “coupled” or “linked” to another element, this may include not only a direct connection relationship but also an indirect connection relationship in which intervening elements are present. Additionally, unless expressly stated to the contrary, “comprise” or “include” when used in this specification, specifies the presence of stated elements but does not preclude the presence or addition of one or more other elements.

In an embodiment of the present disclosure, the terms “first”, “second” and the like are used to distinguish an element from another, and do not limit the order or importance between elements unless otherwise mentioned. Accordingly, a first element in an embodiment may be referred to as a second element in other embodiment within the scope of embodiments of the present disclosure, and likewise, a second element in an embodiment may be referred to as a first element in other embodiment.

Unless defined otherwise, it is to be understood that all the terms used herein including technical and scientific terms have the same meaning as those as understood by those who are skilled in the art. It should be understood that the terms defined by dictionaries must be identical with the meanings within the context of the related art, and they should not be ideally or excessively formally defined unless the context clearly dictate otherwise.

In this specification, when a layer is described to be “on” another layer or a substrate, this may mean that the layer may be directly formed on another layer or a substrate, or a third layer may be provided therebetween. In addition, directional expressions such as up, above (upper), an upper surface, and the like may be construed as meanings such as down, below (lower), a lower surface, and the like based on the standard. In other words, spatial directional expressions need to be construed as relative directions and are not to be limitedly construed as meaning absolute directions.

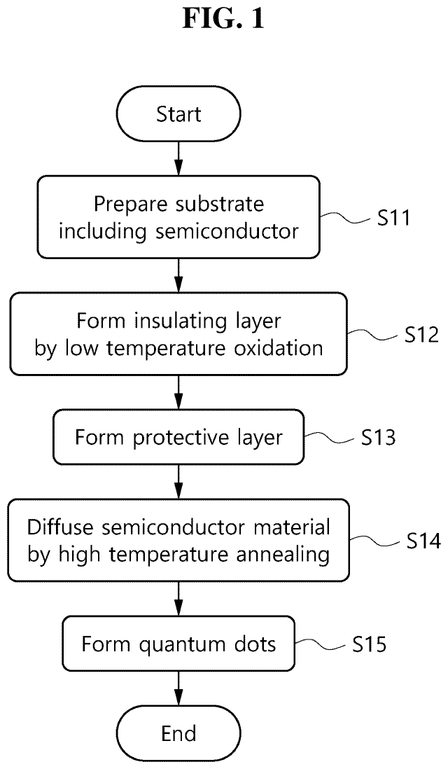

FIG. 1 is a flowchart illustrating steps of a method of fabricating a quantum-dot structure according to an embodiment.

In the present disclosure, a quantum-dot structure at least includes a structure having a quantum confinement effect that the bandgap of a material is changed according to a size of quantum dots, i.e., semiconductor crystals having a size of about a few nanometers. In the present disclosure, the quantum-dot structure may be one that refers to quantum dots themselves or may be one that inclusively refers to a structure including an insulator functioning as a tunneling barrier for the quantum dots along with the quantum dots.

For example, in the present disclosure, the quantum-dot structure may be one that refers to an electronic device, such as a resonant tunneling diode or a single electron transistor, which includes quantum dots and an insulating layer functioning as a tunneling barrier for the quantum dots, thereby controlling current flowing through the quantum dots from an electrode spaced apart from the quantum dots.

Referring to FIG. 1, in order to fabricate the quantum-dot structure, first, a semiconductor material layer including a semiconductor material, which is formed on a substrate, may be prepared (S11). In the present disclosure, the semiconductor material is one corresponding to a material for forming quantum dots. In embodiments of the present disclosure, a semiconductor material forming quantum dots, using germanium (Ge) as an example, is described.

However, the method of fabricating the quantum-dot structure according to the embodiment may be applied to formation of quantum dots using another kind of semiconductor material including a group II-VI semiconductor such as a cadmium-based semiconductor including cadmium sulfide (CdS), etc. or a zinc (Zn)-based semiconductor including zinc sulfide (ZnS) and zinc selenide (ZnSe), etc., an indium (In)-based group III-V semiconductor including indium phosphide (InP), etc., or the like, in addition to germanium (Ge), and is not limited by germanium (Ge)-based processes disclosed in the present disclosure.

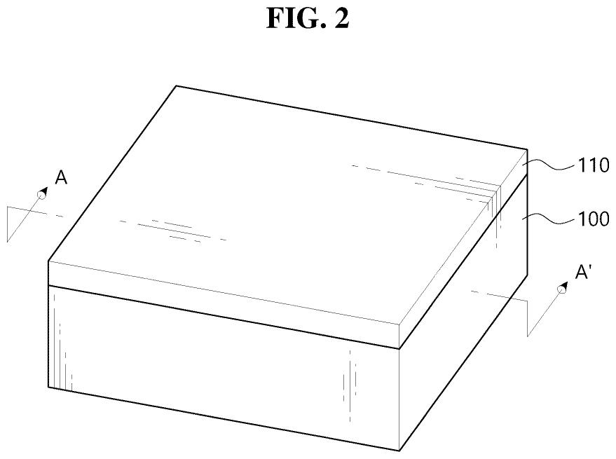

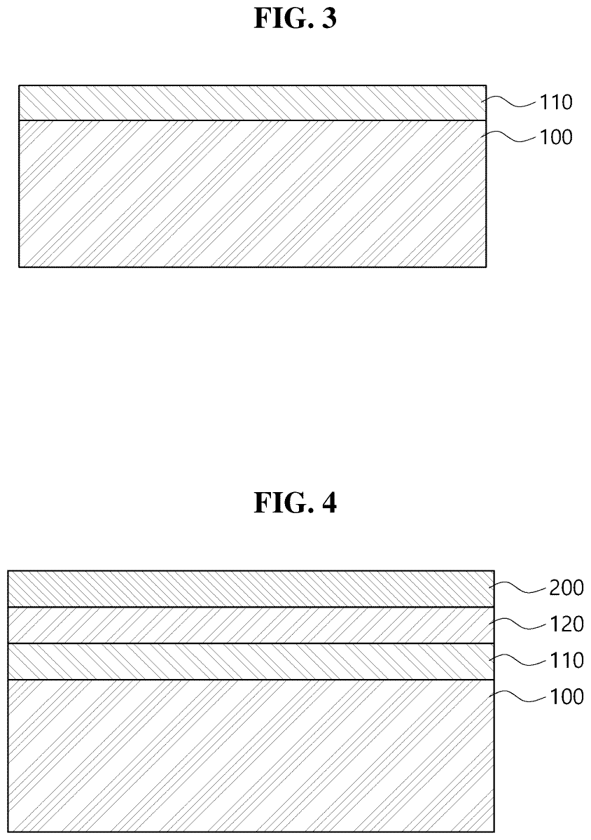

FIG. 2 is a perspective view of a substate 100 on which a semiconductor material layer 110 is formed as a sample for the method of fabricating the quantum-dot structure according to the embodiment, and FIG. 3 is a sectional view taken along line A-A′ of the sample shown in FIG. 2.

According to materials constituting the substrate 100 and the semiconductor material layer 110, the semiconductor material layer 110 may be one epitaxially grown from the substrate 100. For example, in an example, the substrate 100 is a silicon (Si) substrate, and the semiconductor material layer 110 may refer to a silicon germanium (SiGe) layer epitaxially grown from the substrate. However, the material and growth method of the semiconductor material layer 110 are not limited thereto.

Referring to FIGS. 1 and 4, next, an insulating layer 200 may be formed from the semiconductor material layer 110 through an oxidation process (S12). The oxidation process is performed by heating the sample including the substrate 100 and the semiconductor material layer 110 under an atmosphere containing oxygen, but may be made at a relatively low temperature such that the entire semiconductor material layer 110 is not oxidized. For example, in an embodiment, a heating temperature of the sample in a low temperature oxidation process for forming the insulating layer 200 is exceeding 0° C. and less than 600° C. When the heating temperature of the sample in the low temperature oxidation process is 600° C. or higher, there is a problem that the insulating layer is not formed since germanium (Ge) has kinetic energy larger than diffusion energy, and remaining as a germanium (Ge) element itself becomes stable as compared with forming oxide by being bonded to oxygen.

In addition, in an embodiment, the lower temperature oxidation process may be performed under an atmosphere in which oxygen is supplied at a flow rate of 20 sccm. Further, in an embodiment, the sample in the lower temperature oxidation process may be heated for 10 to 30 minutes.

However, a heating temperature, a heating time, and an oxygen concentration in the low temperature oxidation process may be appropriately set according to embodiments, and are not limited to numerical values described in the present disclosure.

As oxygen is injected and thermal energy is transferred from a surface through the low temperature oxidation process, a portion of the semiconductor material layer 110 is changed into the insulating layer 200. For example, when the semiconductor material layer 110 is made of silicon germanium (SiGe), a portion of an upper surface of the semiconductor material layer 110 is oxidized, to be changed into a silicon dioxide (SiO₂) insulating layer 200. In addition, in an embodiment, a portion of the semiconductor material layer 110 in the low temperature oxidation process may form a mixture layer 120 in which a semiconductor material (e.g., SiGe) and oxygen (O) are mixed. That is, the mixture layer 120 may be made of silicon germanium oxide.

In an embodiment, the silicon germanium oxide may be expressed as SiₓGe₁₋ₓO_{y}, and x and y are real numbers between 0 and 1. Growth is difficult when a germanium (Ge) content is about a half or more as compared with the entire metal component. Hence, in an embodiment, the range of x may be exceeding 0.5 and less than 1. In addition, in an embodiment, y has a value which is about two times of x, but the present disclosure is not limited thereto.

In the low temperature oxidation process according to the embodiment, the heating temperature is controlled to less than a diffusion temperature of a semiconductor material such as germanium (Ge). In addition, the oxidation process is performed at a relatively low temperature, so that a thickness of the insulating layer 200 and the mixture layer 120, with which the semiconductor material is diffused to form quantum dots in a subsequent annealing process, can be controlled within a predetermined range.

For example, in an embodiment, the heating temperature and/or the heating time in the oxidation process may be adjusted such that a sum of thicknesses of the mixture layer 120 and the insulating layer 200 becomes about 10 nm or less. The mixture layer 120 and the insulating layer 200 function as a tunneling barrier for quantum dots after the quantum dots are formed through the subsequent annealing process, and thus the thickness of the mixture layer 120 and the insulating layer 200 is limited to a certain range, so that the tunneling barrier can be prevented from being excessively thickened.

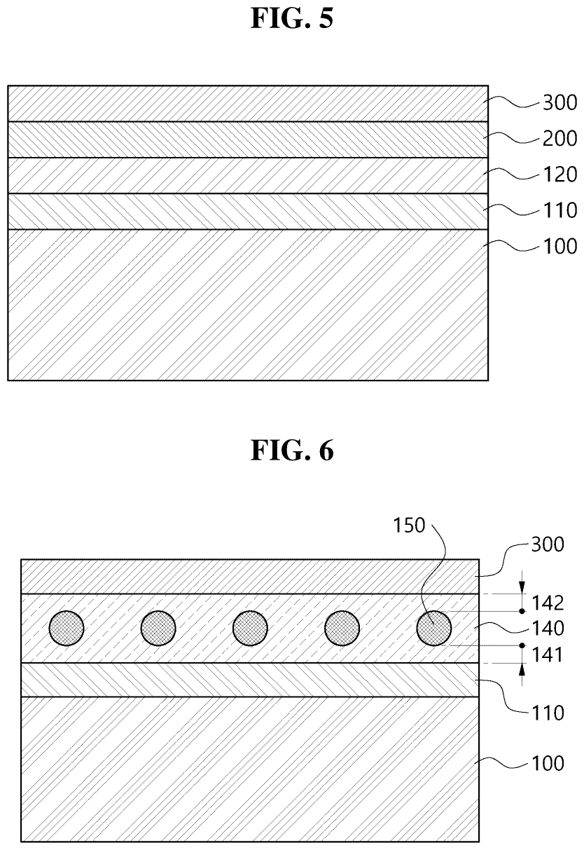

Referring to FIGS. 1 and 5, in an embodiment, a protective layer 300 may be further formed on the insulating layer 200 after the insulating layer 200 is formed through the low temperature oxidation process (S13). The protective layer 300 functions to interrupt a reaction of the sample with an atmosphere inside a furnace in a subsequent high temperature annealing process. For example, the protective layer 300 may be made of titanium nitride (TiN), silicon germanium (SiGe), or the like, but the present disclosure is not limited thereto. Further, the protective layer 300 may be formed by a deposition method such as ultra-high vacuum chemical vapor deposition (UHV-CVD) or another appropriate method according to materials constituting the protective layer 300, and is not limited to one formed through a specific process.

Meanwhile, the protective layer 300 may be removed by a method such as etching in a final device after fabrication of the quantum-dot structure is completed, or may remain on the insulating layer 200 without being removed to operate as a portion or the entirety of an electrode for applying an electric field to the quantum dots.

Referring to FIGS. 1 and 6, the high temperature annealing process is performed on the sample in which the insulating layer 200 is formed through the above-described low temperature oxidation process, to induce diffusion of the semiconductor material into the insulating layer 200 (S14).

In the present disclosure, “low temperature” and “high temperature” are construed as relative meanings that refer to process temperatures for achieving a target result in each process. In the low temperature oxidation process, “low temperature” refers to a process temperature at which the thickness of the mixture layer 120 in which the oxygen is mixed and the insulating layer 200 becomes a thickness thin enough to be suitable for the tunneling barrier for the quantum dots while the semiconductor material is not diffused and the semiconductor material layer 110 is partially oxidized. For example, the low temperature may refer to a temperature of less than 600° C., but the present disclosure is not limited thereto. On the contrary, when the temperature in the oxidation process (S12) is too high, the entire semiconductor material layer 110 is changed into the insulating layer 200, which may result in that the thickness of the tunneling barrier is excessively thick when quantum dots are formed subsequently.

In addition, in the high temperature annealing process, “high temperature” refers to a process temperature high enough that the semiconductor material is diffused into the insulating layer 200 and the diffused semiconductor materials are aggregated to form quantum dots 150. For example, the high temperature may refer to a temperature of 600° C. or higher, but the present disclosure is not limited thereto. When the temperature in the annealing process (S14) is, for example, less than 600° C., which is too low, the oxidation progresses but the diffusion of the semiconductor material is impossible. Therefore, it is difficult for the quantum dots 150 to be formed.

In an embodiment, the heating temperature of the high temperature annealing process may be 700° C. or higher. In addition, in an embodiment, the heating temperature of the high temperature annealing process may be 850° C. or higher. Further, in an embodiment, the atmosphere inside the furnace in the high temperature annealing process may be composed of an inert gas such as nitrogen (N₂) or may be maintained in a state in which the flow rate of a gas is as low as possible when including the gas instead of the inert gas. When the protective layer 300 including titanium nitride (TiN), etc. is formed on the insulating layer 200, the protective layer 300 may function to block the sample from external gas.

When the sample is annealed at a temperature sufficiently high enough that the semiconductor material can be diffused, the semiconductor material in the semiconductor material layer 110 and/or the mixture layer 120 (FIG. 5) is diffused (S14), and the quantum dots 150 which are crystals of the semiconductor material located in an insulating layer 140 are formed through aggregation between the diffused semiconductor material (S15). The quantum dots 150 are located in the insulating layer 140 and surround by the insulating layer, and hence (i) a distance 141 between the quantum dots 150 and the semiconductor material layer 110 therebelow and (ii) a distance 142 between the quantum dots 150 and the protective layer 300 thereabove function as the tunneling barrier for the quantum dots.

For example, when an electric field is applied from the top to the bottom of FIG. 6, electrons tunnel the tunneling barrier thickness 141 from the semiconductor material layer 110 and move to the quantum dots 150, and tunnel the tunneling barrier thickness 142 from the quantum dots 150 and move to the protective layer 300. Although not shown in the drawing, a mixture layer may be located between the semiconductor material layer 110 and the insulating layer 140, and electrons may tunnel the tunneling barrier thickness 141 from the mixture layer and move to the quantum dots 150.

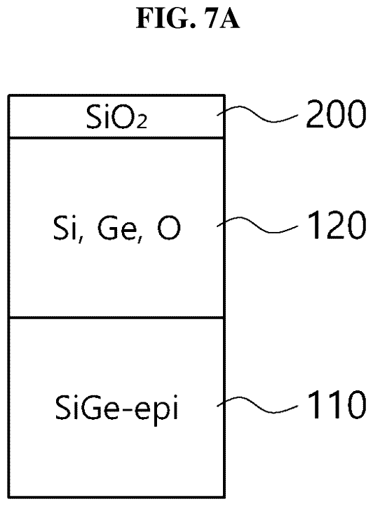

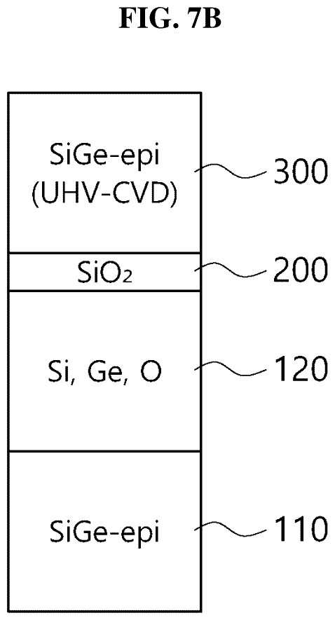

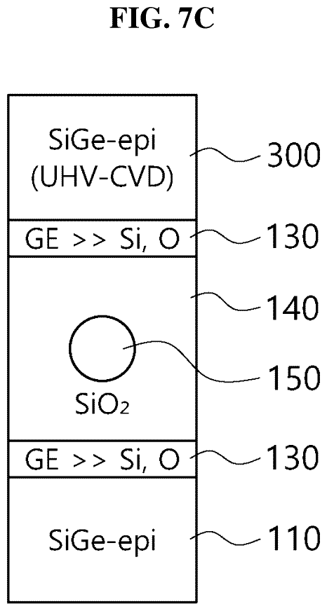

FIG. 7 is a conceptual view illustrating a process of forming quantum dots through self-assembly by the method of fabricating the quantum-dot structure according to the embodiment.

Referring to FIG. 7A, as a low oxidation process is performed on a semiconductor material layer 110 made of silicon germanium (SiGe), which is epitaxially grown on a substrate, oxygen and thermal energy are introduced from above to the semiconductor material layer 110, and therefore, a mixture layer 120 containing silicon (Si), germanium (Ge), and oxygen (O) and an insulating layer 200 containing silicon dioxide (SiO₂) may be formed on the semiconductor material layer 110.

Next, referring to FIG. 7B, a protective layer 300 made of a conductive material may be formed on a sample including the mixture layer 120 and the insulating layer 200. In an embodiment, the protective layer 300 may be made of silicon germanium (SiGe) like the semiconductor material layer 110 so as to subsequently function as an electrode, and may be formed on the insulating layer 200, using an arbitrary method including an epitaxy method, a deposition method through deposition such as UHV-CVD, and the like. However, this is merely illustrative, and the protective layer 300 may be made of titanium nitride (TiN) or another different material.

Next, referring to FIG. 7C, the semiconductor material, i.e., the germanium (Ge) in the semiconductor material layer 110 and the mixture layer 120 is diffused into the insulating layer 200 through a high temperature annealing process, and therefore, quantum dots 150 located in an insulating layer 140 may be formed through self-assembly. In an embodiment, a mixture layer 130 in which germanium (Ge) not aggregated as the quantum dots 150 is mixed with the silicon (Si) and the oxygen (O) may be formed on and/or under the insulating layer 140 including the quantum dots 150 formed through the self-assembly.

As shown in FIG. 7C, the quantum-dot structure according to the embodiment of the present disclosure includes the semiconductor material layer 110, the insulating layer 140 located on the semiconductor material layer 110, and the semiconductor quantum dots 150 which is formed from the semiconductor material diffused into the insulating layer 140 and is located in the insulating layer 140. The quantum dots 150 are electrically isolated from an external layer including the semiconductor material layer 110 and/or the protective layer 300 thereabove by a tunneling barrier formed by the insulating layer 140.

In an embodiment, the mixture layer 130 on the insulating layer 140 and the protective layer 300 on the mixture layer 130 may function as a first electrode (e.g., a drain electrode) for applying an electric field to the quantum dots 150. In addition, the mixture layer 130 under the insulating layer 140 and the semiconductor material layer 110 under the mixture layer 130 may function as a second electrode (e.g., a source electrode) for applying an electric field to the quantum dots 150. That is, a resonant tunneling diode including a source electrode, quantum dots, and a drain electrode can be implemented using the quantum-dot structure according to the embodiment.

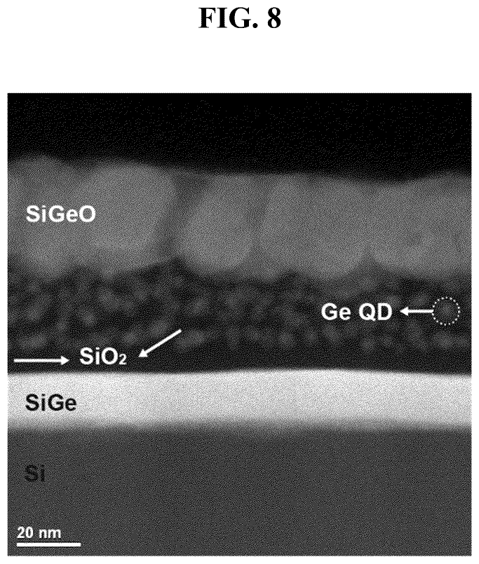

FIG. 8 is a scanning transmission electron microscopy (STEM) image showing a result obtained by forming quantum dots by the method of fabricating the quantum-dot structure according to the embodiment.

The image shown in FIG. 8 shows a result obtained when the present inventors observe a section of a quantum-dot structure formed by the method of fabricating the quantum-dot structure according to the embodiment, using an STEM. In fabrication of the quantum-dot structure shown in FIG. 8, a sample was used as one in which an undoped silicon germanium (SiGe) epitaxy layer containing silicon (Si) and germanium (Ge), of which ratio was 1:1, and having a thickness of about 40 nm was formed as a semiconductor material layer on a p-type silicon (Si) substrate having a thickness of about 525 μm.

A low temperature oxidation process on the sample was performed for 20 minutes under a condition in which a temperature inside a furnace was 550° C. and a pressure inside the furnace was 10 torrG. In addition, titanium nitride (TiN) as a protective layer on an insulating layer was deposited to a thickness of about 20 nm. A high temperature annealing process after the low temperature oxidation process was performed for 20 minutes under a condition in which a temperature inside the furnace was 900° C., a flow rate of oxygen was 0.1 sccm, and a pressure inside the furnace was 0.1 torrG.

As a result obtained by fabricating the quantum-dot structure by applying the above process conditions, a plurality of germanium (Ge) quantum dots having a diameter of about 5 to 6 nm were formed inside a silicon dioxide (SiO₂) insulating layer as shown in FIG. 8. However, the size and shape of the quantum dots shown in FIG. 8 are merely illustrative, and the size of semiconductor quantum dots according to the method of fabricating the quantum-dot structure according to the embodiment may be controlled within a desired range by adjusting the process temperature and/or the process time in the low oxidation process and the process temperature and/or the process time in the high temperature annealing process.

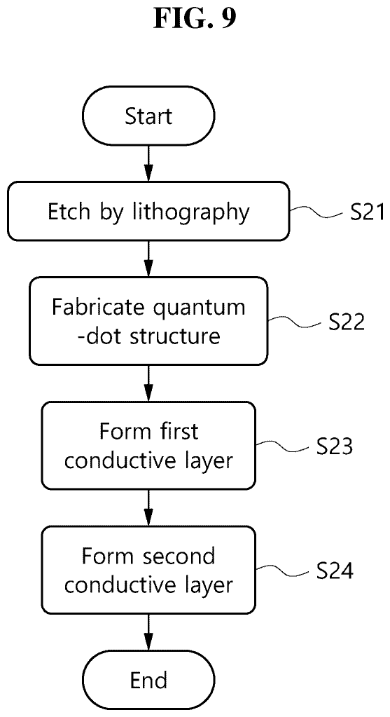

FIG. 9 is a flowchart illustrating steps of a process of fabricating a transistor including a quantum-dot structure as a method of fabricating a quantum-dot structure according to another embodiment.

Referring to FIG. 9, a sample including a semiconductor material layer 110 and an insulating layer 200 on a substrate is prepared through the above-described processes, and may be etched through lithography (S21). When a mixture layer 120 located between the semiconductor material layer 110 and the insulating layer 200 and/or a protective layer 300 located on the insulating layer 200 exist, the mixture layer 120 and the protective layer 300 may also be etched like the insulating layer 200.

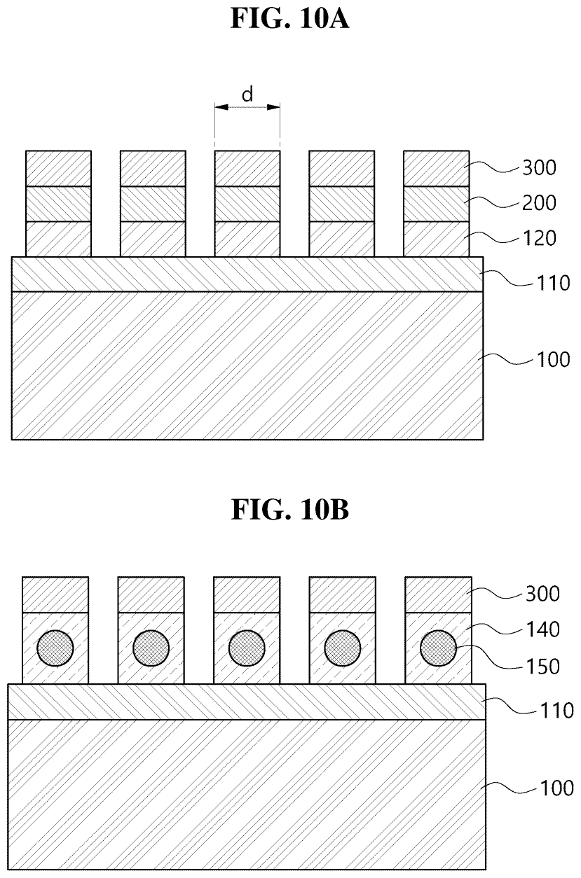

FIG. 10A is a view exemplarily showing an etching result according to the above-described process. Referring to FIG. 10A, the insulating layer 200 may be etched in the shape of nanopillars having a predetermined width (d) through a lithography process (S22). The width (d) of the nanopillars may be determined as a size small enough that, when quantum dots are formed through a subsequent annealing process, each nanopillar has a volume in which only one quantum dot is to be formed in each nanopillar. The volume of each nanopillar sufficiently becomes small, to fabricate a single electron transistor including one quantum dot in each nanopillar. For example, the width of the etched nanopillar may be a few to a few tens of nm.

Meanwhile, the size of the quantum dots 150 and the width (d) of the nanopillars, which are shown in the drawings of the present disclosure, are merely illustrative for convenience of description, and it will be easily understood by those having ordinary skill in the art that the quantum dots and the nanopillars are not illustrated in proportion to the actual size and aspect ratio of the quantum dots and the nanopillars.

An etching method of the nanopillars may be made by an ordinary lithography method of disposing a mask on the protective layer 300 at an uppermost portion of the sample and removing a partial region through exposure, development, and etching, and its detailed description will be omitted to clarify the gist of the present disclosure.

Next, referring to FIGS. 9 and 10B, a high temperature annealing process is performed on the sample etched in the shape of the nanopillars, and therefore, quantum dots 150 located in an insulating layer 140 may be formed through aggregation between diffused semiconductor materials (S22). A process of forming the quantum dots 150 by annealing is the same as described with reference to FIGS. 6 to 8, and therefore, its detailed description will be omitted to avoid redundancy.

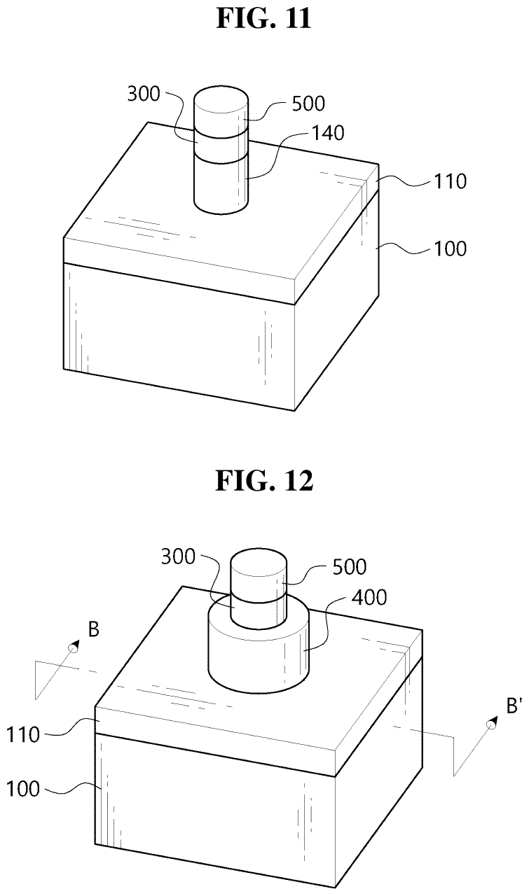

Next, referring to FIGS. 9 and 11, a first conductive layer 500 may be formed on the sample in the shape of the nanopillars (S23). The first conductive layer 500 is a portion functioning as a drain electrode in the single electron transistor fabricated using the sample in the shape of the nanopillars, and may be formed of another arbitrary conductive material such as titanium nitride (TiN), silicon germanium (SiGe), or a metal.

In the embodiment shown in FIG. 9, it has been described that the first conductive layer 500 corresponding to an upper electrode is formed after the quantum dots are formed in the sample in the shape of the nanopillars. However, according to embodiments, the quantum dots in the insulating layer 140 may be formed through a high temperature annealing process after the first conductive layer 500 is formed and etched.

Next, referring to FIGS. 9 and 12, a second conductive layer 400 surrounding the insulating layer 140 including the quantum dot 150 may be formed (S24). The second conductive layer 400 is a portion functioning as a gate electrode in the single electron transistor fabricated using the sample in the shape of the nanopillars, and may be disposed in a shape which is located on the semiconductor material layer 110 and surrounds a side surface of the insulating layer 140 including the quantum dot 150. Also, like the first conductive layer 500, the second conductive layer 400 may be formed of a metal or another different conductive material.

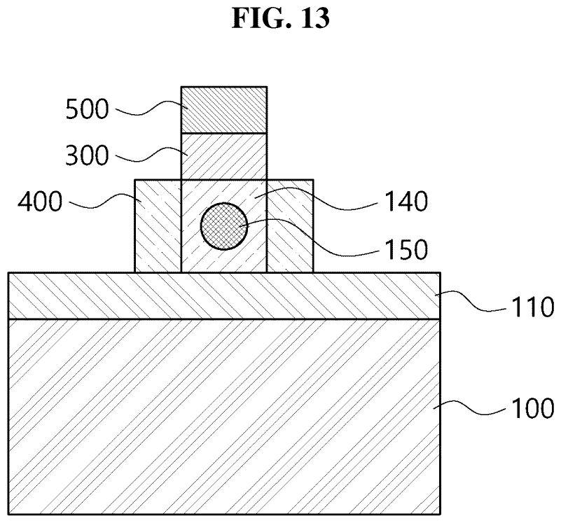

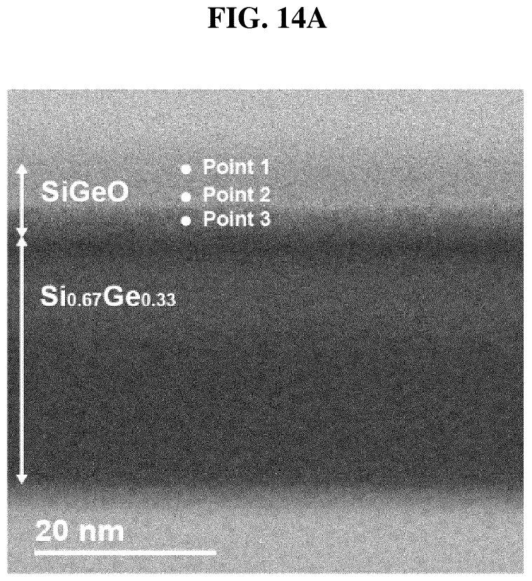

FIG. 13 is a sectional view taken along line B-B′ of the transistor shown in FIG. 12.

Referring to FIG. 13, in the quantum-dot structure according to this embodiment, the protective layer 300 and the first conductive layer 500 thereon function as a drain electrode of the transistor, and the semiconductor material layer 110 on the substrate 100 functions as a source electrode of the transistor. In addition, the second conductive layer 400 surrounding the insulating layer 140 functions as a gate electrode for adjusting an energy level of the semiconductor quantum dot 150. That is, the energy level of the semiconductor quantum dot 150 is determined by an electric field applied to the second conductive layer 400, and accordingly, it is possible to selectively control a flow of electrons which face the first conductive layer 500 while passing through the tunneling barrier of the insulating layer 140 and the quantum dot 150 from the semiconductor material layer 110.

In the fabrication of the quantum-dot structure as described above, the insulating layer 140 and the quantum dots 150 are formed using self-assembly through a low temperature oxidation process and a high temperature annealing process. The insulating layer 140 may function not only as a tunneling barrier between the source electrode and the drain electrode but also as an insulator between the quantum dots 150 and the gate electrode. That is, according to this embodiment, germanium (Ge) quantum dots can be formed through self-assembly without any additional materials except oxygen injected in oxidation of germanium (Ge), and a quantum dot tunneling barrier and silicon dioxide (SiO₂) functioning as a gate oxide film can be simultaneously formed.

Furthermore, in the embodiments of the present disclosure described above, since germanium (Ge) as a material of the quantum dots and silicon (Si) forming the insulating layer are elements of a same carbon group, processes used for existing silicon (Si)-based elements can be equally applied to the other processes except the process of forming the quantum dots through diffusion of the semiconductor material, and accordingly, electronic devices such as a quantum dot-based single electron transistor can be easily fabricated.

In the embodiments of the present disclosure described above, the quantum-dot structure based on the germanium (Ge) quantum dots has been fabricated through self-assembly.

However, the method of fabricating the quantum-dot structure according to the embodiments is not implemented while being limited to the germanium (Ge) quantum dots, and the quantum dots may be formed as some of the elements constituting the sample are diffused through a heating process of the sample. In addition, the method of fabricating the quantum-dot structure according to the embodiments of the present disclosure may be applied to arbitrary materials with which the insulating layer can be formed at a periphery of the quantum dot through self-assembly by some of the elements constituting the sample.

Meanwhile, since the quantum-dot structures according to the embodiments of the present disclosure include the quantum dots formed in the insulating layer, the quantum-dot structures according to the embodiments of the present disclosure can be applied as a memory device based on charge storage characteristics of quantum dots and an optoelectronic device capable of precisely controlling light emission characteristics by adjusting the size and distribution of quantum dots.

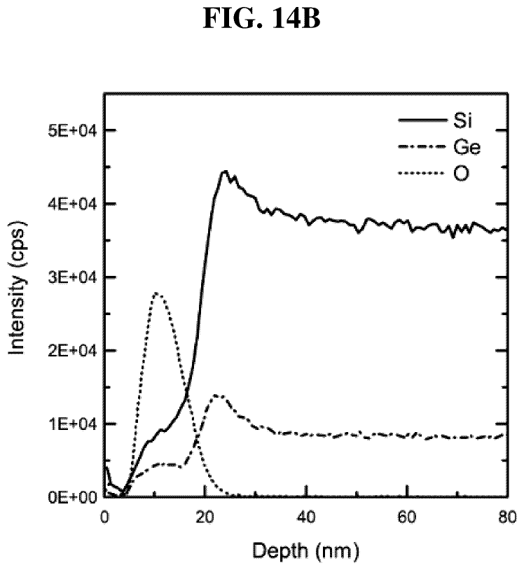

FIG. 14A is an image showing a result obtained by measuring a section after oxidation of a silicon germanium (SiGe) layer at a temperature of 600° C., using a scanning transmission electron microscopy (STEM). As shown in the drawing, a silicon germanium oxide (SiGeO) mixture layer with a thickness of about 26.8 nm was formed from a surface of the silicon germanium (SiGe) layer after the oxidation.

FIG. 14B is a graph showing a secondary ion mass spectrometry (SIMS) result of silicon germanium oxide shown in FIG. 14A, and shows a peak intensity according to an element distribution for each depth.

In addition, the following Table 1 shows energy dispersive X-ray spectroscopy (EDS) analysis results of element distribution amounts for heights designated as ‘point 1,’ ‘point 2,’ and ‘point 3’ in FIG. 14A.

TABLE 1

| | Si (%) | Ge (%) | O (%) |
|---|---|---|---|
| SiGeO (point 1) | 36.94 | 3.26 | 59.80 |
| SiGeO (point 2) | 40.13 | 4.11 | 55.77 |
| SiGeO (point 3) | 42.66 | 21.09 | 36.24 |

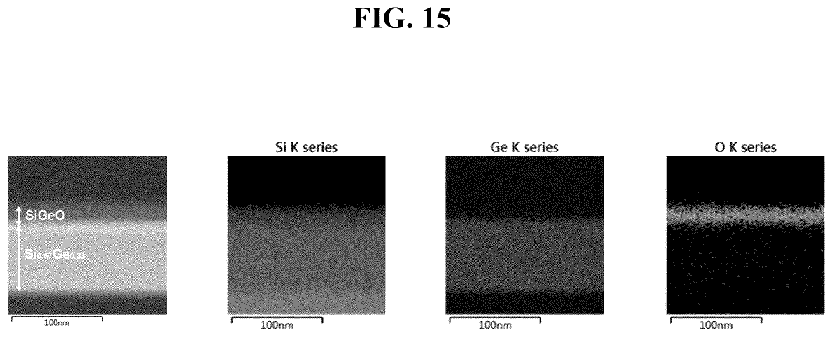

In addition, FIG. 15 is an image showing an EDS element mapping result of the silicon germanium oxide shown in FIG. 14A. As shown in FIG. 14B, Table 1, and FIG. 15, it can be seen that silicon (Si), germanium (Ge), and oxygen (O) atoms are located to a certain thickness from a surface.

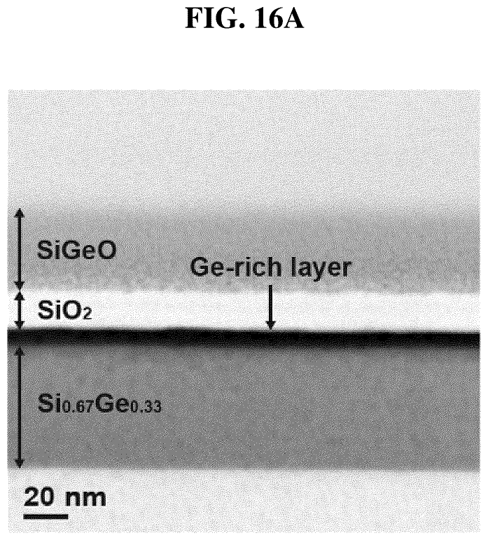

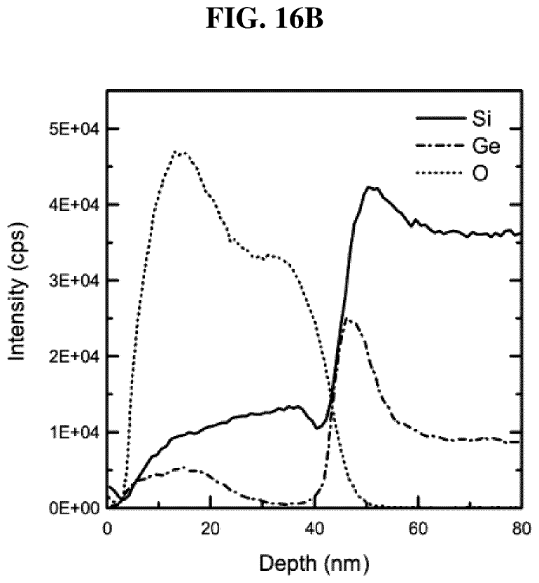

FIG. 16A shows a result obtained by measuring a section after oxidation of the silicon germanium (SiGe) layer at a temperature of about 850° C., using the STEM. Referring to FIG. 16A, a silicon dioxide (SiO₂) layer with a thickness of about 18.4 nm from the surface after the oxidation was formed, and a high concentration germanium (Ge) layer with a thickness of about 7.2 nm was formed between the silicon dioxide (SiO₂) layer and the silicon germanium (SiGe) layer.

FIG. 16B is a graph showing a SIMS result of the silicon germanium oxide shown in FIG. 16A, and shows a peak intensity according to an element distribution for each depth. As shown in the drawing, it can be seen that the intensity of a graph of the germanium element (Ge) suddenly increase in a section of a depth of about 40 to 50 nm, which is located below from the surface, and therefore, a high concentration germanium (Ge) layer is located between the silicon dioxide (SiO₂) layer and the silicon germanium (SiGe) layer.

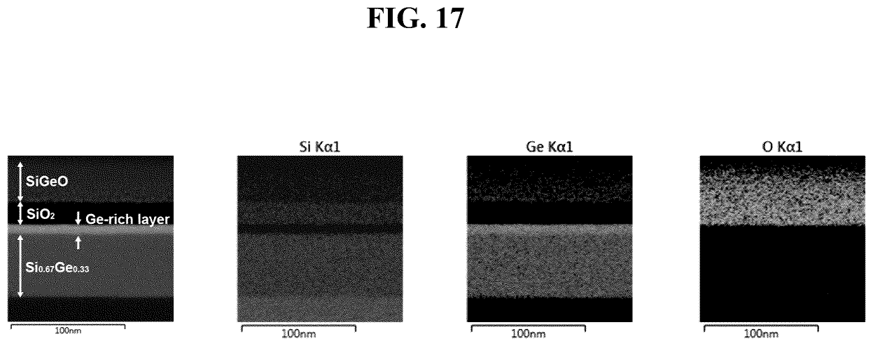

The following Table 2 shows an EDS analysis result of an element distribution amount of each layer shown in FIG. 16A, and FIG. 17 is an image showing an EDS element mapping result of the silicon germanium oxide shown in FIG. 16A. Like FIG. 16A, these show existence of a high concentration germanium (Ge) layer (Ge-rich layer, GRL) between the silicon dioxide (SiO₂) layer and the silicon germanium (SiGe) layer.

TABLE 2

| | Si (%) | Ge (%) | O (%) |
|---|---|---|---|
| SiGeO | 28.45 | 2.06 | 69.49 |
| SiO₂ | 32.48 | 0.21 | 67.31 |
| GRL | 16.39 | 69.59 | 14.01 |

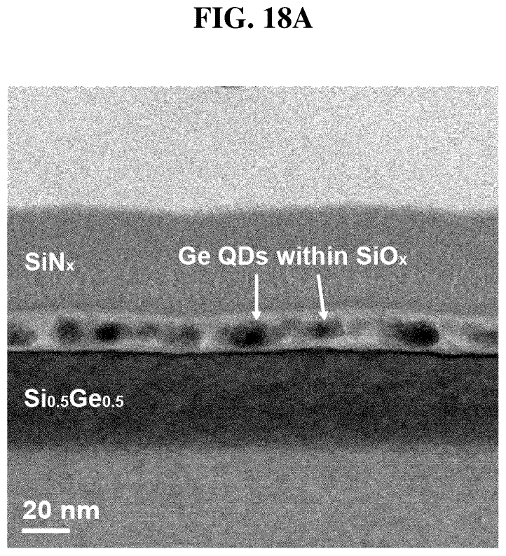

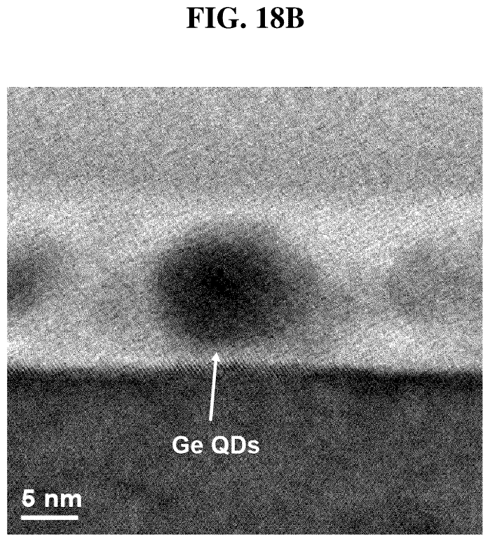

FIGS. 18A and 18B are images showing a result obtained by forming germanium (Ge) quantum dots in an insulating layer.

First, the present inventors oxidized two layers respectively made of silicon germanium (SiGe) and silicon (Si) at about 600° C., thereby forming a silicon germanium oxide (SiGeO) mixture layer on the remaining silicon germanium (SiGe) layer. After that, the present inventors deposited a silicon nitride (SiN) layer on the mixture layer, and formed germanium (Ge) quantum dots in the insulating layer by continuously performing annealing at about 1000° C. and about 700° C.

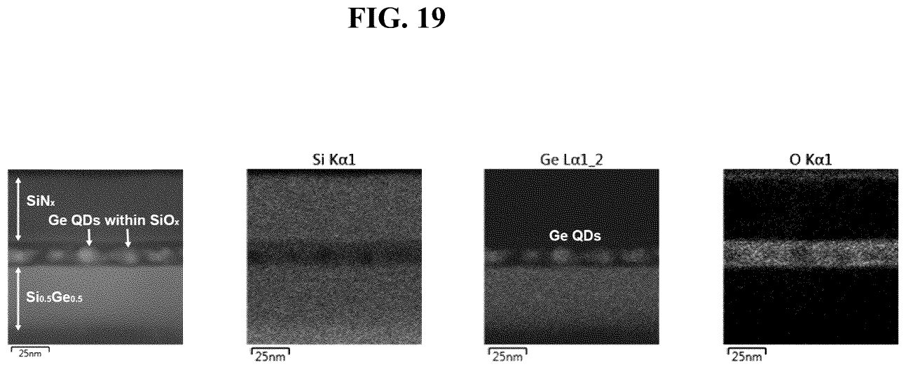

FIG. 18A shows a result obtained by measuring a section of a quantum-dot structure including the germanium (Ge) quantum dots formed as described above, using the STEM, and the quantum-dot structure includes a silicon (Si) layer, a silicon germanium (SiGe) layer, a silicon dioxide and germanium quantum dot (SiO₂+Ge QD) layer, and a silicon nitride (SIN) layer from the bottom thereof. FIG. 18B shows an image obtained by close-up photographing germanium (Ge) quantum dots in an insulating layer as another STEM measurement result performed on the same quantum-dot structure. As shown in the drawing, according to an embodiment of the present disclosure, it can be seen that germanium (Ge) quantum dots with a size of about 9 nm are formed. Further, FIG. 19 is an image showing an EDS element mapping result of the quantum-dot structure shown in FIGS. 18A and 18B.

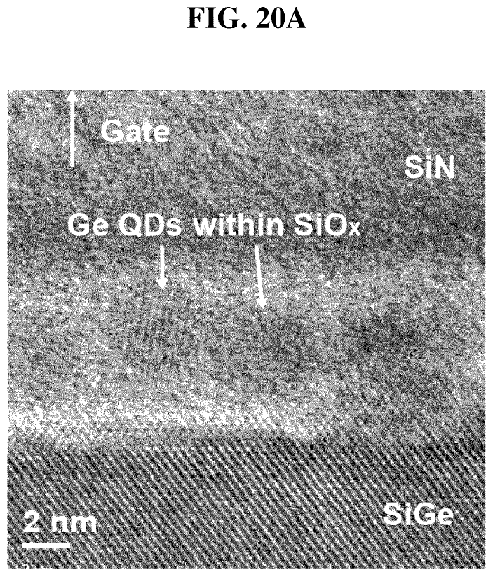

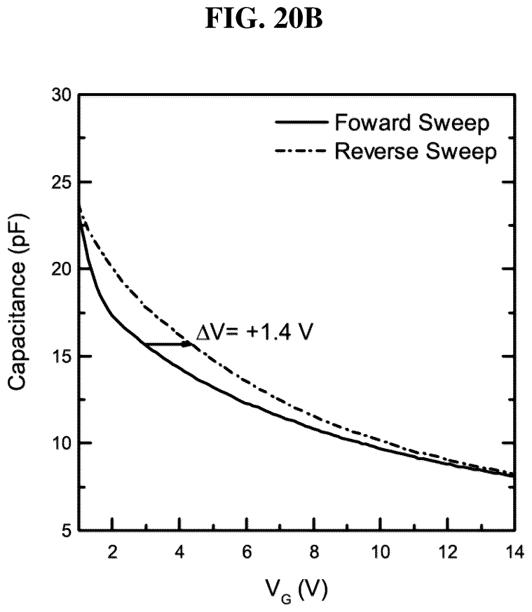

FIG. 20A is an image showing a result obtained by measuring a section of the quantum-dot structure in which the germanium quantum dots exist in the insulating layer, using the STEM.

According to an embodiment, the present inventors formed germanium (Ge) quantum dots in the insulating layer, using the following method. First, the present inventors oxidized two layers respectively made of silicon germanium (SiGe) and silicon (Si) at a temperature of about 600° C., thereby forming a silicon germanium oxide (SiGeO) mixture layer on the remaining silicon germanium (SiGe) layer. After that, the present inventors deposited silicon nitride (SiN) on the mixture layer, and formed germanium (Ge) quantum dots in the insulating layer by continuously performing annealing at about 1000° C. and about 800° C.

As shown in FIG. 20A, the quantum-dot structure fabricated using the above-described method includes a silicon (Si) layer, a silicon germanium (SiGe) layer, a silicon dioxide and germanium quantum dot (SiO₂+Ge QD) layer, and a silicon nitride (SiN) layer from the bottom thereof.

FIG. 20B is a graph showing a capacitance-voltage (C-V) measurement result of the quantum-dot structure shown in FIG. 20A, and after a quantum-dot structure was fabricated using the method described with reference to FIG. 20A, an aluminum (Al) gate electrode was deposited on the quantum-dot structure. After that, a capacitance-voltage (C-V) was measured by sweeping a positive voltage to the gate electrode from about −10 V to about +20 V and then re-sweeping a negative voltage to the gate electrode from about +20 V to about −10 V. As shown in the drawing, it can be seen that, as charges are trapped in the quantum dots within the insulating layer in a process of sweeping the positive voltage, a phenomenon that a capacitance-voltage (C-V) curve moves rightward in subsequent negative voltage sweeping is observed, and therefore, germanium (Ge) quantum dots are formed in the insulating layer.

As described above, the quantum-dot structures according to the embodiments of the present disclosure include the quantum dots with a nanometer size, which are formed in the insulating layer, so that various electrical and optical characteristics applicable to quantum dot-based devices can be realized.

The capacitance-voltage (C-V) curve shown in FIG. 20B shows that the quantum-dot structure according to the embodiment is applicable as a memory device having a charge storage function. Specifically, a phenomenon that charges are trapped in quantum dots in positive voltage sweeping, and therefore, the C-V curve exhibits hysteresis in subsequent negative voltage sweeping shows that the charges are stably stored in the quantum dots. By using such characteristics, the quantum dot structures according to the embodiments of the present disclosure can be effectively applied to flash memories or next-generation charge trap memory structures.

In addition, according to experimental results of the present inventors, a germanium (Ge) concentration distribution and a remaining germanium (Ge) concentration, which are formed according to oxidation conditions, have influence on a size, a density, and a space distribution of quantum dots. Accordingly, the size and density of quantum dots are precisely controlled, so that light emitting wavelengths can be controlled, and the quantum-dot structures according to the embodiments of the present disclosure can be applied to an optical device such as a photoelectronic device or a quantum light source.

While the present disclosure has been hereinabove described with reference to the embodiments shown in the drawings, this is provided for illustration purposes only and it will be appreciated by those having ordinary skill in the art that various modifications and variations may be made thereto. However, it should be noted that such modifications fall in the technical protection scope of the present disclosure. Therefore, the true technical protection scope of the present disclosure should be defined as including other embodiments and other examples by the technical spirit of the appended claims and the equivalents to the appended claims.

What is claimed is:

1. A method of fabricating a quantum-dot structure, the method comprising the steps of:
preparing a semiconductor material layer formed on a substrate;
forming an insulating layer from a portion of the semiconductor material layer by oxidizing the semiconductor material layer; and
forming quantum dots which are located in the insulating layer and are made of a semiconductor material by diffusing the semiconductor material into the insulating layer by annealing.

2. The method of fabricating a quantum-dot structure according to claim 1, wherein preparing the semiconductor material layer comprises epitaxially growing the semiconductor material layer from the substrate.

3. The method of fabricating a quantum-dot structure according to claim 2,
wherein the substrate comprises silicon (Si), and
wherein the semiconductor material layer comprises silicon germanium (SiGe).

4. The method of fabricating a quantum-dot structure according to claim 1, wherein forming the insulating layer comprises oxidizing a portion of the semiconductor material layer by heating the semiconductor material layer while injecting oxygen.

5. The method of fabricating a quantum-dot structure according to claim 4, wherein forming the insulating layer further comprises forming a mixture layer comprising a semiconductor material and oxygen between the semiconductor material layer and the insulating layer.

6. The method of fabricating a quantum-dot structure according to claim 4, wherein forming the insulating layer comprises heating the semiconductor material layer at a temperature of exceeding 0° C. and less than 600° C. under an atmosphere comprising oxygen.

7. The method of fabricating a quantum-dot structure according to claim 5, wherein forming the quantum dots comprises inducing diffusion of a semiconductor material into the insulating layer from the semiconductor material layer and the mixture layer by annealing.

8. The method of fabricating a quantum-dot structure according to claim 7,
wherein the mixture layer comprises silicon germanium oxide, and
wherein the quantum dots are made of germanium (Ge).

9. The method of fabricating a quantum-dot structure according to claim 1, wherein forming the quantum dots comprises heating the semiconductor material layer and the insulating layer at a temperature of 600° C. or higher to induce diffusion of a semiconductor material.

10. The method of fabricating a quantum-dot structure according to claim 1,
wherein forming the quantum dots comprises adjusting at least one of a heating time and a heating temperature of the semiconductor material layer and the insulating layer to adjust a size of the quantum dots.

11. The method of fabricating a quantum-dot structure according to claim 1, further comprising:
forming a protective layer for interrupting a reaction on the insulating layer after forming the insulating layer and before forming the quantum dots.

12. The method of fabricating a quantum-dot structure according to claim 11,
wherein the protective layer comprises titanium nitride (TiN).

13. The method of fabricating a quantum-dot structure according to claim 1, further comprising:
etching the insulating layer in a shape of nanopillars before forming the quantum dots,
forming a first conductive layer on the insulating layer; and
forming a second conductive layer surrounding the insulating layer in the shape of the nanopillars on the semiconductor material layer.

14. A quantum-dot structure comprising:
a semiconductor material layer;
an insulating layer located on the semiconductor material layer; and
quantum dots formed from a semiconductor material diffused into the insulating layer to be located in the insulating layer,
wherein the quantum dots are electrically isolated from the semiconductor material layer by a tunneling barrier formed by the insulating layer.

15. The quantum-dot structure according to claim 14,
wherein the semiconductor material layer comprises silicon germanium (SiGe),
wherein the insulating layer comprises silicon dioxide (SiO₂), and
wherein the quantum dots are made of germanium (Ge).

16. The quantum-dot structure according to claim 14, further comprising:
a mixture layer located between the insulating layer and the semiconductor material layer, the mixture layer including a semiconductor material and oxygen.

17. The quantum-dot structure according to claim 14,
wherein the insulating layer including the quantum dots has the shape of nanopillars.

18. The quantum-dot structure according to claim 14, further comprising:
a first conductive layer located on the insulating layer; and
a second conductive layer located on the semiconductor material layer, the second conductive layer surrounding the insulating layer.

19. The quantum-dot structure according to claim 18,
wherein the quantum dots are electrically isolated from the first conductive layer and the second conductive layer by a tunneling barrier formed by the insulating layer.

20. A single electron transistor comprising the quantum-dot structure according to claim 14.

21. A quantum-dot structure fabricated by the steps of:
preparing a semiconductor material layer formed on a substrate;
forming an insulating layer from a portion of the semiconductor material layer by oxidizing the semiconductor material layer; and
forming quantum dots which are located in the insulating layer and are made of a semiconductor material by diffusing the semiconductor material into the insulating layer by annealing.
